(19) United States
(12) Patent Application Publication
(10) Pub. No.: US 2026/0343737 A1
(43) Pub. Date: Oct. 29, 2026

(54) ANTI-DEFECT GLASS SUBSTRATE STRUCTURE AND GLASS SUBSTRATE MANUFACTURING METHOD

(71) Applicant: UNIMICRON TECHNOLOGY CORP., Taoyuan City (TW)

(72) Inventors: Chien-Chen Lin, Taoyuan City (TW); Heng-Ming Nien, Taoyuan City (TW)

(21) Appl. No.: 19/229,701

(22) Filed: Jun. 5, 2025

(30) Foreign Application Priority Data
Apr. 24, 2025 (TW) 114115572

(51) Int. Cl. H05K 1/03; H05K 1/02; H05K 3/00; H05K 3/46

(52) U.S. Cl. CPC H05K 1/0306; H05K 1/0271; H05K 3/002; H05K 3/0052; H05K 3/4644; H05K 2201/09481; H05K 2201/096; H05K 2201/09618

(57) ABSTRACT

An anti-defect glass substrate structure includes a glass substrate with a first surface, a first buffer layer mounted on the first surface, and a first circuit layer mounted on the first buffer layer. A first buffer layer opening of the first buffer layer exposes the first surface of the glass substrate, and a first buffer area of the first buffer layer is mounted on an edge of the first buffer layer opening. The first circuit layer includes a first side wall and a first groove structure. The first groove structure is formed on the first side wall, and the first groove structure exposes the first buffer area. The first groove structure inhibits the glass substrate from developing Seware defects, thus preventing Seware defects from impacting the first circuit layer.

### CROSS-REFERENCE TO RELATED APPLICATION(S)

This application claims the priority benefit of TW application serial No. 114115572 filed on Apr. 24, 2025, the entirety of which is hereby incorporated by reference herein and made a part of the specification.

### BACKGROUND OF THE INVENTION

### 1. Field of the Invention

The present invention relates to a glass substrate structure and a manufacturing method, and more particularly to an anti-defect glass substrate structure and a glass manufacturing method.

### 2. Description of the Related Art

In a field of fabricating circuits on glass substrates, the glass substrate is placed alongside other dielectric material carrier boards on a same surface, and the dielectric material carrier boards reserve a scribe line exposing the glass substrate. After circuit layers are formed on the glass substrate, a router will groove the glass substrate into small units along the scribe line.

However, the scribe line area situated between the glass substrate and the carrier boards often experiences a mismatch in coefficients of thermal expansion (CTE) with the materials of the redistribution layer (RDL) carried on the glass substrate, such as the mismatch in the CTEs between the copper traces and dielectric materials. While thermal excursion exists between the scribe line and the RDL, there will be stress caused by solidification shrinkage, therefore causing stress accumulation on a boundary between the glass substrate and the RDL within the scribe line, which further causes Seware defects. Thereafter, Seware defects will extend into the glass substrate by time, and further causes bigger and more recognizable breaches, so eventually leading to the glass substrate unable to support the RDL steadily.

Moreover, the term “Seware defects” refers to “SeWaRe”, which is cited from multiple research papers on IEEE Transactions on Device and Materials Reliability by Scott R. McCann. The research papers explain the mechanism of Seware defect, and further discuss the transmission on material stress.

With reference to FIGS. 4A and 4B, which present the current process of glass substrate production. First, a glass substrate structure 100 is formed. Then, the glass substrate structure 100 is divided into multiple substrate unit structures 101 by laser LS grooving along the scribe line 102 reserved on the glass substrate structure 100. In detail, the glass substrate structure 100 has a circuit layer 104 mounted on a glass substrate 103. When the glass substrate 100 is divided into multiple substrate unit structures 101 by laser LS grooving, the energy that the laser impacts on the scribe line 102 will cause a boundary 105 between the glass substrate 103 and the circuit layer 104 within the scribe line 102 to experience extreme stress. This stress is due to the solidification shrinkage of materials with different CTEs after being heated. Therefore, Seware defects 106 will occur at the boundary 105 between the glass substrate 103 and the circuit layer 104 within the scribe line 102, and the Seware defect 106 will continue to crack and extend, affecting the glass substrate 103 and preventing it from stably supporting the circuit layer 104.

With reference to FIGS. 5 and 6, in one experiment, the glass substrate 100 supports a dielectric material of Ajinomoto Build-up Film (ABF), and is precut into four glass substrate unit structures 101 with two scribe lines 102. Most importantly, even without grooving the scribe lines 102 on the glass substrate unit structures 101, as shown in FIG. 5, it will cause spontaneous ablation in about 3 days when the glass substrate structure 100 is at rest, and will further cause defects, as shown in FIG. 6.

The experiment proves that even without heating up the boundary 105 of the glass substrate 103 and the circuit layer 104 within the scribe lines 102 with the Laser LS, the glass substrate structure 100 will still cause spontaneous Seware defects 106 on the boundary 105 due to stress accumulation in the multilayer structure, and then defects eventually accumulate into the configuration that the glass substrate 103 is unable to support the circuit 104 stably, as shown in FIG. 6.

### SUMMARY OF THE INVENTION

The present invention provides an anti-defect glass substrate structure and a glass substrate manufacturing method.

The anti-defect glass substrate structure of the present invention includes:
a glass substrate, including a first surface;
a first buffer layer, mounted on the first surface and including:
   a first buffer layer opening, exposing the first surface of the glass substrate;
   a first buffer area, mounted on an edge of the first buffer layer opening;
a first circuit layer, mounted on the first buffer layer and including:
   a first side wall;
   a first groove structure, formed on the first side wall, and exposing the first buffer area.

The glass substrate manufacturing method of the present invention includes the steps of:
forming a first buffer layer on a first surface of a glass substrate;
forming a first circuit layer on the first buffer layer; wherein the first circuit layer includes a first barrier layer, and the first barrier layer adheres to the first buffer layer;
forming a first scribe line on the first circuit layer; wherein the first scribe line cuts through the first circuit layer and contacts the first barrier layer;
wet etching the first barrier layer to form a first groove structure; and
photolithographically exposing the first buffer layer in the first scribe line to form a first buffer layer opening and a first buffer area in the first buffer layer; wherein the first buffer area is formed in the edge of the first buffer layer opening, and the first groove structure is exposed in the first buffer area.

The present invention features the first buffer layer in order to buffer the stress accumulation, and significantly reduces the possibility of spontaneous Seware defect occurring on the boundary between the first circuit layer and the glass substrate. Moreover, while grooving the anti-defect glass substrate structure of the present invention, the groove structure covers the boundary, i.e., structurally avoiding the laser irradiation, between the first circuit layer and the glass substrate of the boundary, thereby directing the laser-induced heat away from the boundary and preventing grooving-induced Seware defects. Thus, the present invention ensures that the circuit layer can be more stably mounted on the glass substrate.

### BRIEF DESCRIPTION OF THE DRAWINGS

FIG. 1 is a schematic cross-sectional diagram of an embodiment of an anti-defect glass substrate structure of the present invention;

FIG. 2 is a schematic cross-sectional diagram of another embodiment of the anti-defect glass substrate structure of the present invention;

FIGS. 3A to 3G are schematic cross-sectional diagrams for manufacturing the anti-defect glass substrate structure of the present invention;

FIG. 4A is a schematic cross-sectional diagram of a glass substrate structure;

FIG. 4B is a schematic cross-sectional diagram of a glass substrate unit structure;

FIG. 5 is a schematic top diagram of the glass substrate structure; and

FIG. 6 is a schematic top diagram of a defect glass substrate structure.

### DETAILED DESCRIPTION OF THE INVENTION

The present invention provides an anti-defect glass substrate structure and a glass substrate manufacturing method.

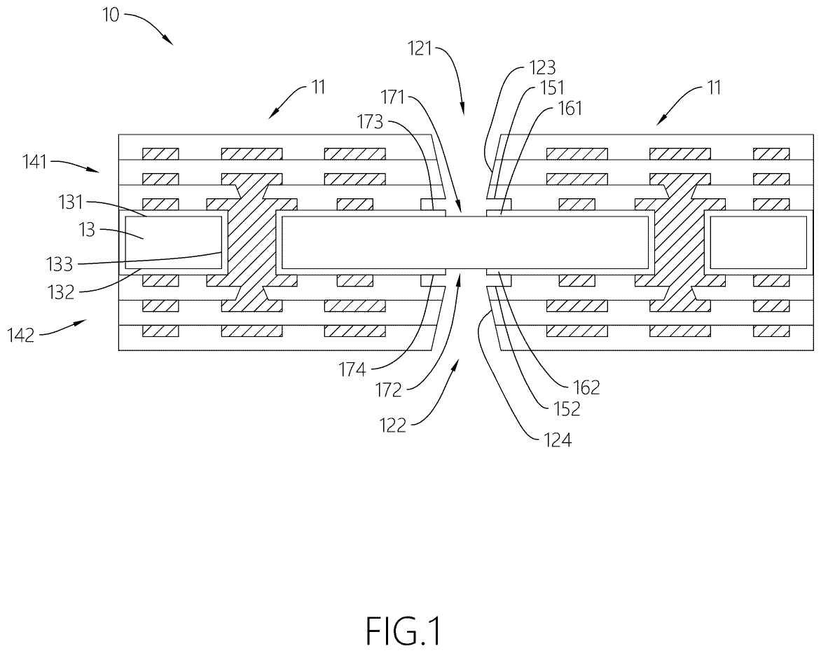

With reference to FIG. 1, in one embodiment, the anti-defect glass substrate structure 10 includes at least one scribe line for a router to perform laser grooving, thereby dividing the glass substrate into multiple substrate unit structures 11.

In detail, with reference to FIG. 1, the glass substrate structure 10 includes a glass substrate 13 with a first surface 131 and a second surface 132 opposite to the first surface 131.

The first surface 131 on the glass substrate 13 forms a first buffer layer 161, and the first buffer layer 161 forms a first circuit layer 141. Moreover, the first buffer layer 161 includes a first buffer layer opening 171 and a first buffer area 173, wherein the first buffer layer opening 171 exposes the first surface 131 on the glass substrate 13, and the first buffer area 173 is mounted on an edge of the first buffer layer opening 171. Furthermore, the first circuit layer 141 includes a first scribe line 121 with a first side wall 123 and a first groove structure 151, wherein the first scribe line 121 cuts through the first circuit layer 141 and down to the first buffer layer opening 171. In addition, the first groove structure 151 is concaved on the first side wall 123, and exposes the first buffer area 173.

In a preferred embodiment, there is also a second buffer layer 162 formed on the second surface 132 on the glass substrate 13, and further a second circuit layer 142 is formed on the second buffer layer 162. Moreover, the second buffer layer 162 includes a second buffer layer opening 172 and a second buffer area 174, where the second buffer layer opening 174 exposes the second surface 132 on the glass substrate 13, and the second buffer area 174 is mounted on an edge of the second buffer layer opening 172. Furthermore, the second circuit layer 142 includes a second scribe line 122 with a second side wall 124 and a second groove structure 152, wherein the second scribe line 122 cuts through the second circuit layer 142 and down to the second buffer layer opening 172. In addition, the second groove structure 152 is concaved on the second side wall 124, and exposes the second buffer area 174.

The glass substrate structure 10 of the present invention focuses on the groove structure and the mounting of the buffer layer. More specifically, the first buffer layer 161 buffers stress accumulation and significantly reduces the possibility of spontaneous Seware defect occurring on a boundary of the first surface 131 between the first circuit layer 141 and the glass substance 13. Similarly, the second buffer layer 162 buffers stress accumulation and significantly reduces the possibility of spontaneous Seware defect occurring on a boundary of the second surface 132 between the second circuit layer 142 and the glass substance 13. Therefore, no spontaneous ablation will occur to create Seware defects on the first scribe line 121 and the second scribe line 122 when the glass substance structure 10 is at rest.

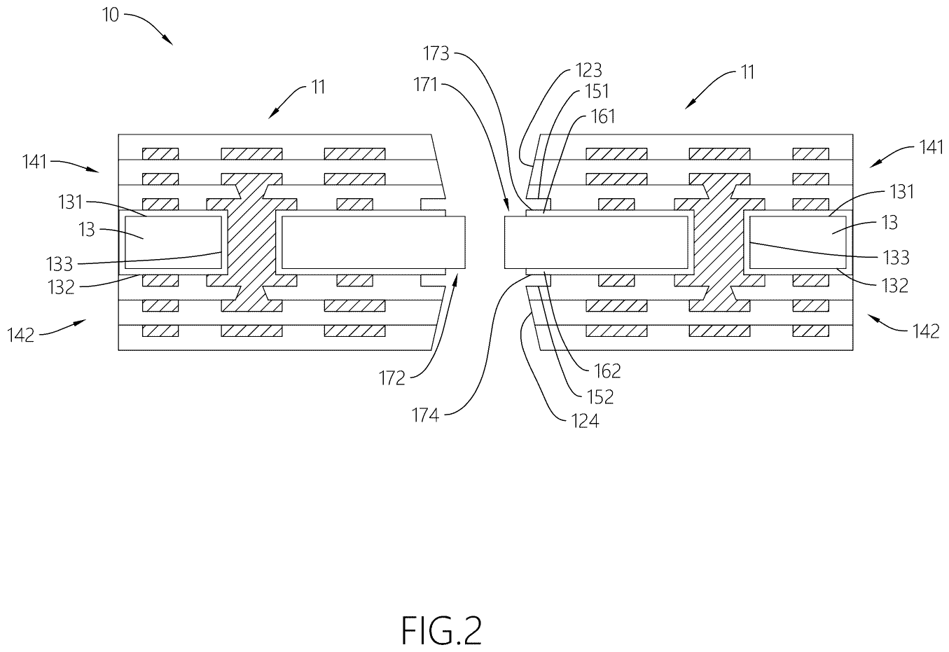

With reference to FIG. 2, where laser grooving divides the glass substrate structure 10 into multiple glass substrate unit structures 11. The first groove structure 151 structurally prevents the laser irradiation on the first surface 131 within the first groove structure 151 because the first groove structure 151 covers the boundary between the first circuit layer 141 and the glass substrate 13 on the first surface 131, thereby directing the laser-induced heat away from the first surface 131 within the first groove structure 151, and preventing grooving-induced Seware defects on the boundary between the first circuit layer 141 and the glass substrate 13 on the first surface 131. Likewise, the second groove structure 152 also covers the boundary between the second circuit layer 142 and the glass substrate 13 on the second surface 142, the second groove structure 152 structurally preventing the laser irradiation of the second surface 132 within the second groove structure 152, thereby directing the laser-induced heat away from the second surface 132 within the second groove structure 152, and preventing grooving-induced Seware defects on the boundary between the second circuit layer 142 and the glass substrate 13 on the second surface 142. As a result, the present invention ensures more stable mounting of the first circuit layer 141 and the second circuit layer 142 on the glass substrate 13.

In one embodiment, the first side wall 123 of the first scribe line 121 has a first slope, where a projection of the first side wall 123 having the first slope is parallel to the first surface 131 of the glass substrate 13. For example, the first side wall 123 having the first slope can be represented as a horizontal projection and a vertical projection in math. The horizontal projection of the first side wall 123 having the first slope is parallel to the first surface 131 of the glass substrate 13, and the vertical projection of the first side wall 123 having the first slope is perpendicular to the first surface 131 of the glass substrate 13. Moreover, the first groove structure 151 includes a groove depth which is longer than the horizontal projection of the first side wall 123 having the first slope.

Likewise, the second side wall 124 of the second scribe line 122 also has a second slope, where a projection of the second side wall 124 having the first slope is parallel to the second surface 132 of the glass substrate 13. For example, the second side wall 124 having the second slope can be represented as a horizontal projection and a vertical projection in math. The horizontal projection of the second side wall 124 having the second slope is parallel to the second surface 132 of the glass substrate 13, and the vertical projection of the second side wall 124 having the second slope is perpendicular to the second surface 132 of the glass substrate 13. Moreover, the second groove structure 152 includes a groove depth which is longer than the horizontal projection of the second side wall 124 having the second slope.

This configuration ensures the groove depth of the first groove structure 151 and the second groove structure 152 are adequately remote from the laser grooving, thus preventing the thermal impact on the boundaries and the Seware defects caused by material and stress accumulation.

Simultaneously, the groove depth of the first groove structure 151 and the second groove structure 152 also ensure that the slight Seware defect caused by the laser grooving won't be able to extend into the first circuit layer 141 and the second circuit layer 142 on the glass substrate 13. This is because there is no contact between the laser grooving, the first circuit layer 141 and the second layer 142 respectively. The laser grooving is located on a partial area on the first surface 131 that is not covered by the first groove structure 151 on the first scribe line 121, and is located on a partial area on the second surface 132 that is not covered by the second groove structure 152 on the second scribe line 122. In other words, the partial areas on the first surface and the second surface do not carry the first circuit layer 141 and the second circuit layer 142 of multilayer circuit structures, and therefore, no additional material stress load is borne from the multilayer circuit structure. As a consequence, the slightly Seware defect can be limited in the particular areas caused by laser grooving, and won't be able to extend to and contact the first circuit layer 141 and the second circuit layer 142. Besides, the forming of the first buffer area 173 of the first buffer layer 161 and the second buffer area 174 of the second buffer layer 174 also suppress the parallel spread of the slight Seware defect in the glass substrate 13 caused by laser grooving in the particular areas. Based on the above, the present invention can prevent Seware defects in many aspects, preventing the impact of the mounting of the first circuit layer 141 and the second circuit layer 142 on the glass substrate 13.

In one embodiment, the first groove structure 151 and the second groove structure 152 have the same depth, and the first buffer layer 161 and the second buffer layer 162 have the same settings. In a preferred embodiment, the first groove structure 151 and the second structure 152 have the depths from 250 μm to 300 μm respectively.

In one embodiment, the first circuit layer 141 and the second circuit layer 142 are multilayer circuit structures, for example, a redistribution layer (RDL) using copper traces and a dielectric material of Ajinomoto Build-up Film (ABF). In another embodiment, the first circuit layer 141 and the second circuit layer 141 can also be multilayer circuit structures that are made of different metals and different dielectric materials.

In one embodiment, the glass substrate 13 forms multiple vias 133 that go through the first surface 131 and the second surface 132. Moreover, the first circuit layer 141 mounted on the first surface 131 and the second circuit layer 142 mounted on the second surface 132 are electrically connected through the vias 133 in the glass substrate 13.

With reference to FIGS. 1 and 2, the glass substrate structure 10 is divided into multiple glass substrate unit structures 11 by grooving along the first scribe line 121 and the second scribe line 122. However, unlike the embodiment shown in FIG. 1, each glass substrate unit structure 11 in FIG. 2 represents another embodiment protected by the present invention. In the embodiment presented in FIG. 2, one of the glass substrate unit structures 11 includes the glass substrate 13, the first circuit layer 141, the first buffer layer 161, the second surface 132 opposite to the first surface 131 on the glass substrate 13, and the first buffer area 173 and the first buffer layer opening 171 on the buffer layer 161. The buffer layer 161 is mounted on the first surface 131, where the first buffer layer opening 171 exposes the first surface 131 of the glass substrate 13, and the first buffer area 173 is mounted on the edge of the first buffer layer opening 171. Furthermore, the first circuit layer 141 includes the first side wall 123 and the first groove structure 151, and the first groove structure 151 connects to the first side wall 123 and the first buffer layer opening 171. In addition, the first groove structure 151 is concaved on the first side wall 123 and exposes the first buffer area 173.

In a preferred embodiment, there is also the second buffer layer 162 formed on the second surface 132, and further the second circuit layer 142 is formed on the second buffer layer 162. Moreover, the second buffer layer 162 includes the second buffer layer opening 172 and the second buffer area 174, where the second buffer layer opening 174 exposes the second surface 132 on the glass substrate 13, and the second buffer area 174 is mounted on an edge of the second buffer layer opening 172. Furthermore, the second circuit layer 142 includes the second side wall 124 and the second groove structure 152, and the second groove structure 152 connects to the second side wall 124 and the second buffer layer opening 172. In addition, the second groove structure 152 is concaved on the second side wall 124, and exposes the second buffer area 174.

In one embodiment, the first side wall 123 includes the first slope, wherein the first slope can be represented as the horizontal projection and the vertical projection in math. The horizontal projection of the first slope is parallel to the first surface 131 of the glass substrate 13, and the vertical projection of the first slope is perpendicular to the first surface 131 of the glass substrate 13. Moreover, the first groove structure 151 includes the groove depth which is longer than the horizontal projection of the first slope.

Additionally, the second side wall 124 includes the second slope, wherein the second slope can be represented as the horizontal projection and the vertical projection in math. The horizontal projection of the second slope is parallel to the second surface 132 of the glass substrate 13, and the vertical projection of the second slope is perpendicular to the second surface 132 of the glass substrate 13. Moreover, the second groove structure 152 includes the groove depth which is longer than the horizontal projection of the second slope.

In one embodiment, the first groove structure 151 and the second groove structure 152 have the same groove depth, and the first buffer layer 161 and the second buffer layer 162 have the same settings. In a preferred embodiment, the groove depth of the first groove structure 151 and the second groove structure 152 are respectively between 250 μm and 300 μm.

In one embodiment, multiple vias 133 are formed in the glass substrate 13, where the vias 133 go through the first surface 131 and the second surface 132. Moreover, the first circuit layer 141 mounted on the first surface 131 and the second circuit layer 142 mounted on the second surface 132 are electrically connected through the vias 133 in the glass substrate.

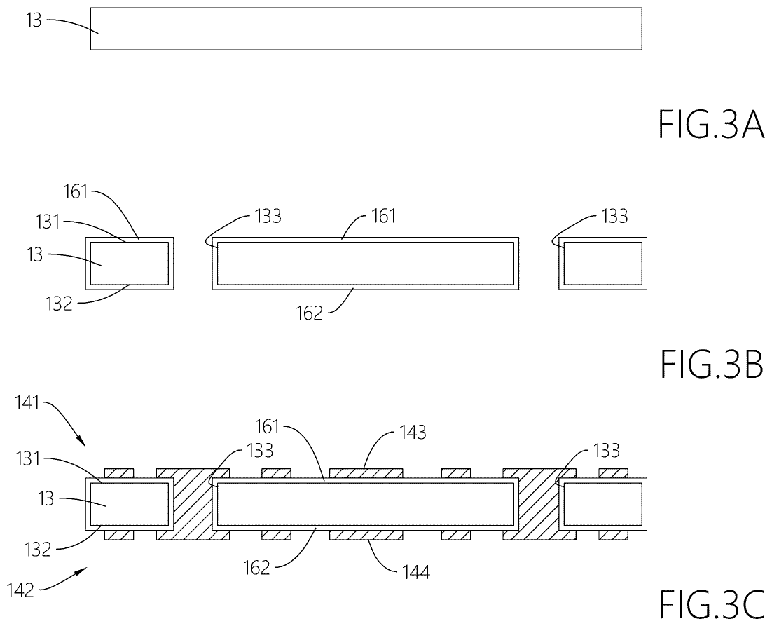

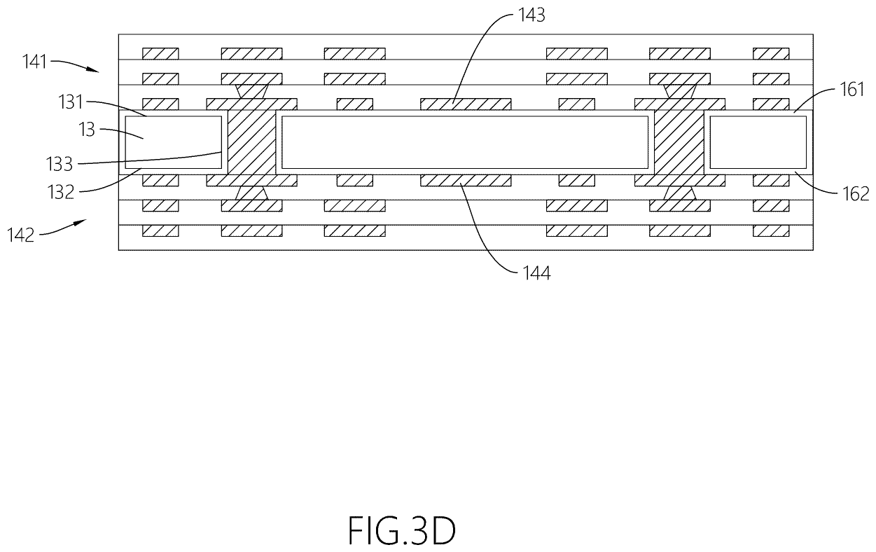

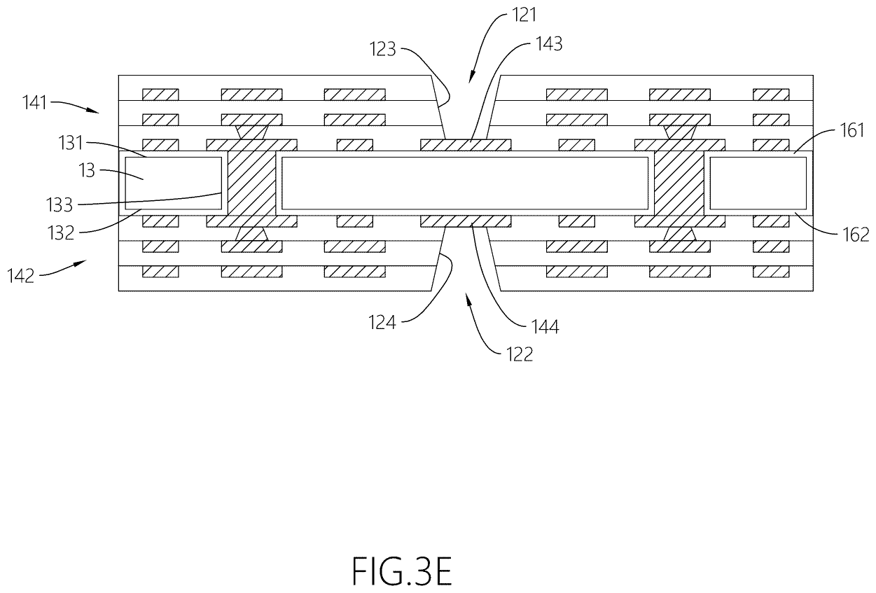

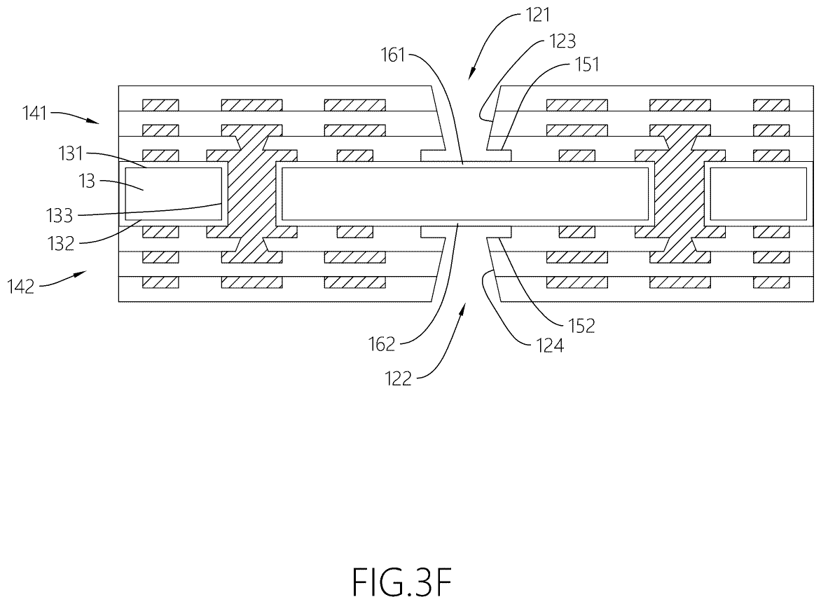

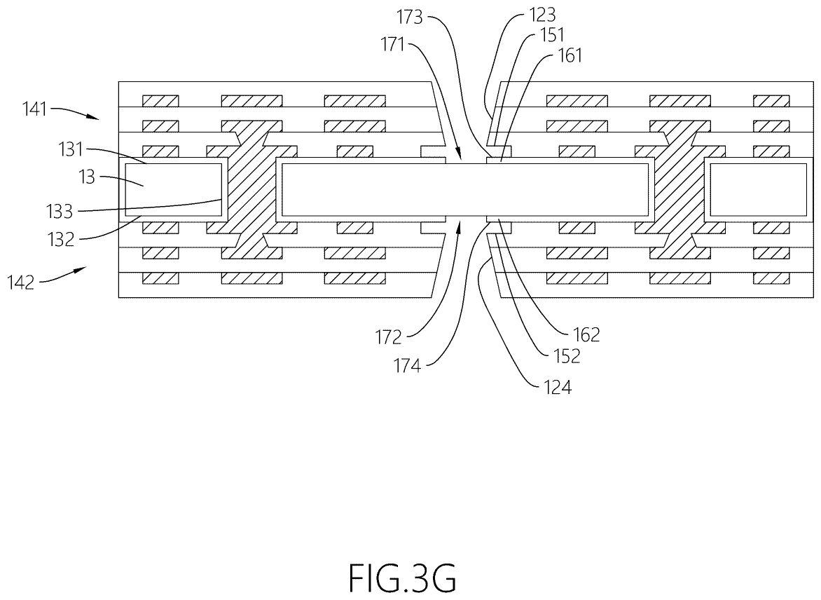

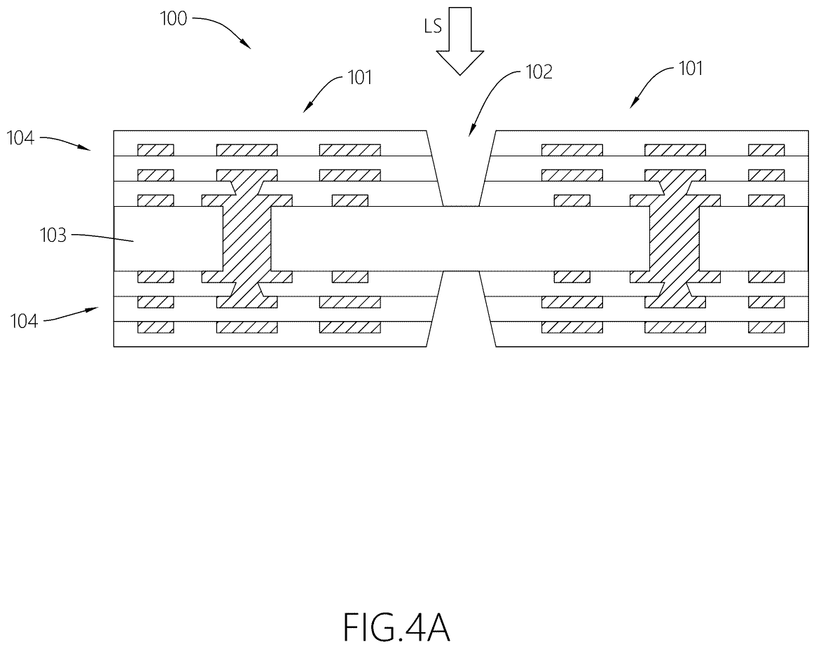

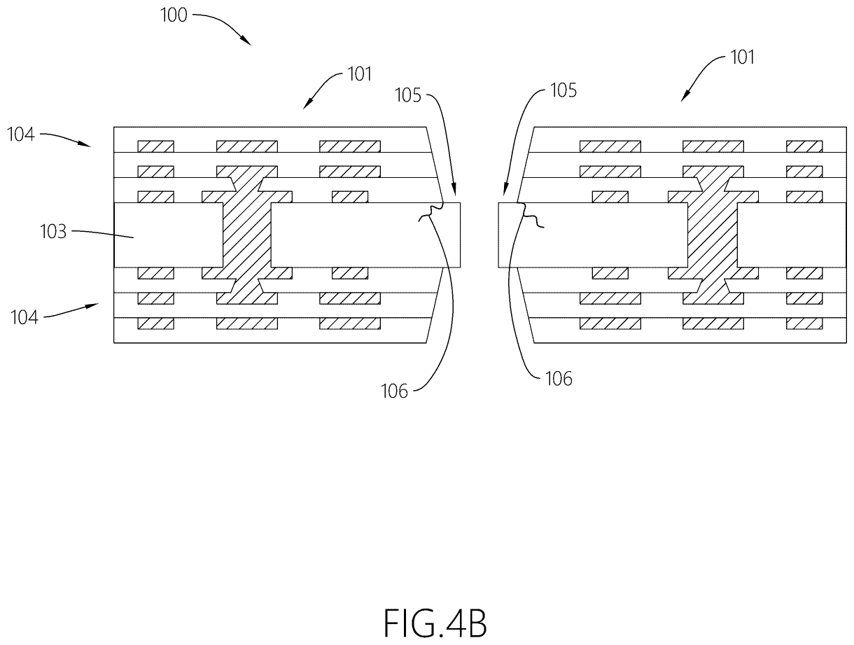

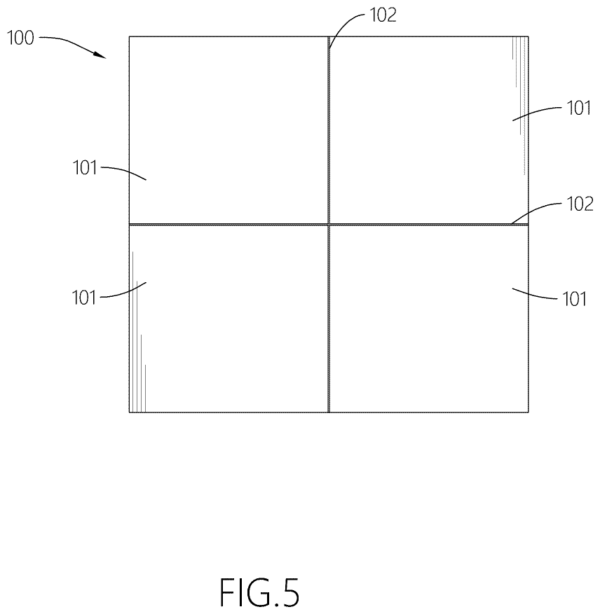

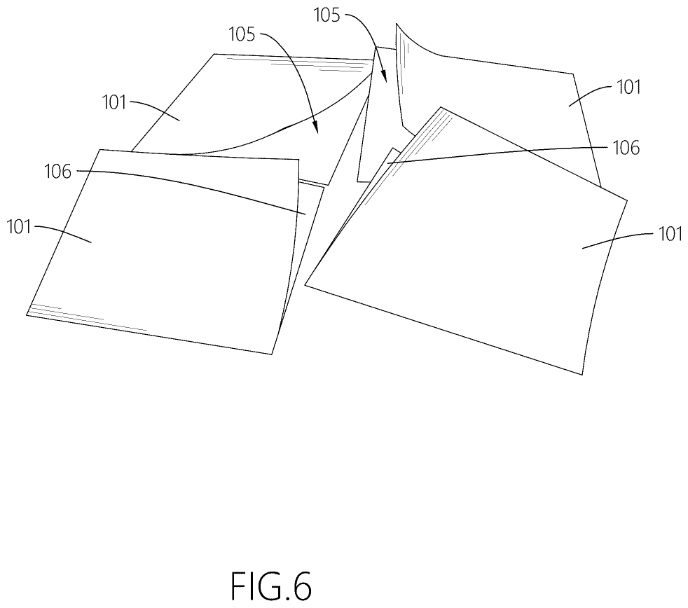

With reference to FIGS. 3A to 3G, the schematic cross-sectional diagrams illustrate the manufacturing method of the anti-defect glass substrate structure 10 of the present invention. The method includes the following steps.

With reference to FIG. 3A, prepare a glass substrate 13.

With reference to FIG. 3B, form multiple vias 133 by perforating the glass substrate 13, and form a buffer layer on the glass substrate 13. Specifically, after forming the multiple vias 133 by perforating the glass substrate 13, form the first buffer layer 161 on the first surface 131 and form the second buffer layer 162 on the second surface 132 on the glass substrate 13.

With reference to FIGS. 3C and 3D, form a circuit layer on top of the buffer layer, wherein the circuit layer includes a barrier layer for bonding the glass substrate 13. Specifically, form the first circuit layer 141 on the first buffer layer 161, and form the second circuit layer 142 on the second buffer layer 162. The first circuit layer includes a first barrier layer 143, which is bonded with the first buffer layer 161; the second circuit layer 142 includes a second barrier layer 144, which is bonded with the second buffer layer 162. The first circuit layer 141 and the second circuit layer 142 are respectively multilayer circuit structures. For conciseness in FIGS. 3C and 3D, the process of forming the first circuit layer 141 and the second circuit layer 142 on the glass substrate 13 using conventional build-up (BU) steps is omitted. In a preferred embodiment, as shown in FIG. 3D, the completed first circuit layer 141 and the second circuit layer 142 are respectively RDLs built from copper traces and ABF. Moreover, the first circuit layer 141 mounted on the first surface 131 and the second circuit layer 142 mounted on the second surface 132 are electrically connected through the vias 133 in the glass substrate 13.

With reference to FIG. 3E, perform etching to form a scribe line on the circuit layer, wherein the scribe line cuts through the circuit layer and contacts the barrier layer. Specifically, form the first scribe line 121 on the first circuit layer 141, wherein the first scribe line 121 cuts through the first circuit layer 143 and contacts the first barrier layer 143; form the second scribe line 122 on the second circuit layer 142, wherein the second scribe line 122 cuts through the second circuit layer 142 and contacts the second barrier layer 144.

With reference to FIG. 3F, perform etching to remove the barrier layer to form a groove structure. Specifically, wet etch the first barrier layer 143 to form the first groove structure 151 within the removed first barrier layer 143 region, and wet etch the second barrier layer 144 to form the second groove structure 152 within the removed second barrier layer 144 region. Therefore, the first buffer layer 161 under the first barrier layer 143 and the second buffer layer 162 under the second barrier layer 144 are exposed.

With reference to FIG. 3G, laser etch the exposed buffer layer in the scribe line to form a buffer layer opening and a buffer area. Specifically, photolithographically expose the first buffer layer 161 in the first scribe line 121 to form the first buffer layer opening 171 and the first buffer area 173; photolithographically expose the second buffer layer 162 in the second scribe line 122 to form the second buffer layer opening 172 and the second buffer area 174. That is, the first groove structure 151 is connected to the first side wall 123 of the first scribe line 121, and the second groove structure 152 is connected to the second side wall 124 of the second scribe line 122. As illustrated in FIG. 3G, the structure is manufactured through the method of the anti-defect glass substrate as the glass substrate structure 10 of FIG. 1.

Moreover, with reference to FIGS. 2 and 3G, the manufacturing method of the anti-defect glass substrate further comprises the following step: groove through the glass substrate 13 which is exposed in the buffer layer opening. Specifically, groove through the glass substrate 13 which is exposed in the first buffer layer opening 171 on the first surface 131, or through the glass substrate 13 which is exposed in the second buffer layer opening 172 on the second surface 132, is also applicable to form the glass substrate unit structures 11 shown in FIG. 2 by grooving the anti-defect glass substrate structure.

What is claimed is:

1. An anti-defect glass substrate structure, comprising:
a glass substrate, comprising a first surface;
a first buffer layer, mounted on the first surface, comprising:
a first buffer layer opening, exposing the first surface of the glass substrate;
a first buffer area, mounted on an edge of the first buffer layer opening;
a first circuit layer, mounted on the first buffer layer and comprising:
a first side wall;
a first groove structure, formed on the first side wall, and exposing the first buffer area.

2. The anti-defect glass substrate structure as claimed in claim 1, wherein the glass substrate has a second surface opposite to the first surface;
wherein, the anti-defect glass substrate structure further comprises:
a second buffer layer, mounted on the second surface and comprising:
a second buffer layer opening, exposing the second surface of the glass substrate;
a second buffer area, mounted on an edge of the second buffer layer opening;
a second circuit layer, mounted on the second buffer layer and comprising:
a second side wall;
a second groove structure, formed on the second side wall, and exposing the second buffer area.

3. The anti-defect glass substrate structure as claimed in claim 1, wherein the first side wall is a side wall of a first scribe line, and the first scribe line cuts through the first circuit layer and communicates with the first buffer layer opening.

4. The anti-defect glass substrate structure as claimed in claim 1, wherein the first side wall has a first slope, and a projection of the first side wall having the first slope is parallel to the first surface of the glass substrate;
wherein the first groove structure comprises a groove depth, and the groove depth is longer than the projection of the first side wall having the first slope.

5. The anti-defect glass substrate structure as claimed in claim 4, wherein the groove depth is from 250 μm to 300 μm.

6. An anti-defect glass substrate manufacturing method, comprising steps of:
forming a first buffer layer on a first surface of a glass substrate;
forming a first circuit layer on the first buffer layer, wherein the first circuit layer comprises a first barrier layer which adheres to the first buffer layer;
forming a first scribe line on the first circuit layer, wherein the first scribe line cuts through the first circuit layer and contacts the first barrier layer;
wet etching the first barrier layer and forming a first groove structure; and
photolithographically exposing the first buffer layer in the first scribe line, thereby forming a first buffer layer opening and a first buffer area in the first buffer layer; wherein the first buffer area is formed in an edge of the first buffer layer opening, and the first groove structure is exposed in the first buffer area.

7. The anti-defect glass substrate manufacturing method as claimed in claim 6, further comprising a step of:
grooving through the glass substrate which is exposed from the first buffer layer opening, thereby grooving the anti-defect glass substrate structure.

8. The anti-defect glass substrate manufacturing method as claimed in claim 6, wherein the glass substrate has a second surface opposite to the first surface, further comprising steps of:
forming a second buffer layer on the second surface of the glass substrate;
forming a second circuit layer on the second buffer layer, wherein the second circuit layer comprises a second barrier layer which adheres to the second buffer layer;
forming a second scribe line on the second circuit layer, wherein the second scribe line cuts through the second circuit layer and contacts the second barrier layer;
wet etching the second barrier layer and forming a second groove structure; and
photolithographically exposing the second buffer layer in the second scribe line, thereby forming a second buffer layer opening and a second buffer area in the second buffer layer; wherein the second buffer area is formed in an edge of the second buffer layer opening, and the second groove structure is exposed in the second buffer area.

9. The anti-defect glass substrate manufacturing method as claimed in claim 6, wherein the first scribe line has a first side wall with a first slope, and a projection of the first side wall having the first slope is parallel to the first surface of the glass substrate;
wherein the first groove structure concaved in the first side wall comprises a groove depth, and the groove depth is longer than the projection of the first side wall having the first slope.

10. The anti-defect glass substrate manufacturing method as claimed in claim 9, wherein the groove depth is from 250 μm to 300 μm.
